(19) United States
(12) Patent Application Publication
(10) Pub. No.: US 2020/0401090 A1
(43) Pub. Date: Dec. 24, 2020

(54) SYSTEMS AND METHODS FOR TIERING OF HEATPIPES

(71) Applicant: Dell Products L.P., Round Rock, TX (US)

(72) Inventors: Travis C. NORTH, Cedar Park, TX (US); Christopher M. HELBERG, Austin, TX (US); Austin M. SHELNUTT, Leander, TX (US)

(73) Assignee: Dell Products L.P., Round Rock, TX (US)

(21) Appl. No.: 16/447,440

(22) Filed: Jun. 20, 2019

(51) Int. Cl. G05B 15/02; G06F 1/20; H05K 7/20

(52) U.S. Cl. CPC G05B 15/02; H05K 7/20663; H05K 7/20336; G06F 1/206

(57) ABSTRACT

An information handling system may include an information handling resource, a heat-rejecting media thermally coupled to the information handling resource, the heat rejecting media comprising and a heatpipe structure comprising a plurality of heatpipes. The plurality of heatpipes may include a generally-cylindrical first pipe mechanically coupled at a location proximate the information handling resource and having a first cross-sectional area, a generally-cylindrical second pipe mechanically coupled to the first pipe having a second cross-sectional area less than the first cross-sectional area, and a generally-cylindrical third pipe mechanically coupled to the second pipe having a third cross-sectional area less than the second cross-sectional area, such that the second pipe is coupled between the first pipe and the third pipe and the first pipe, second pipe, and third pipe form a closed plenum, and a finstack structure comprising a plurality of fins mechanically and thermally coupled to the third pipe.

### TECHNICAL FIELD

The present disclosure relates in general to information handling systems, and more particularly to cooling of information handling system components using heat-rejecting media, including heatpipes.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

As processors, graphics cards, random access memory (RAM) and other components in information handling systems have increased in clock speed and power consumption, the amount of heat produced by such components as a side-effect of normal operation has also increased. Often, the temperatures of these components need to be kept within a reasonable range to prevent overheating, instability, malfunction and damage leading to a shortened component lifespan. Accordingly, air movers (e.g., cooling fans and blowers) have often been used in information handling systems to cool information handling systems and their components.

To control temperature of components of an information handling system, an air mover may direct air over one or more heatsinks thermally coupled to individual components. In some embodiments, a heatsink may be coupled to a device it cools via a heatpipe and an evaporator thermally and mechanically coupled over the device. As heat generated by information handling system components increases, a need has arisen for the evaporator to cover more of the device all the while providing a heatpipe to transfer heat from the evaporator to the heatsink in an effective manner.

### SUMMARY

In accordance with the teachings of the present disclosure, the disadvantages and problems associated with traditional approaches to heat-rejecting media may be substantially reduced or eliminated.

In accordance with embodiments of the present disclosure, an information handling system may include an information handling resource, a heat-rejecting media thermally coupled to the information handling resource, the heat rejecting media comprising and a heatpipe structure comprising a plurality of heatpipes. The plurality of heatpipes may include a generally-cylindrical first pipe mechanically coupled at a location proximate the information handling resource and having a first cross-sectional area, a generally-cylindrical second pipe mechanically coupled to the first pipe having a second cross-sectional area less than the first cross-sectional area, and a generally-cylindrical third pipe mechanically coupled to the second pipe having a third cross-sectional area less than the second cross-sectional area, such that the second pipe is coupled between the first pipe and the third pipe and the first pipe, second pipe, and third pipe form a closed plenum, and a finstack structure comprising a plurality of fins mechanically and thermally coupled to the third pipe.

In accordance with these and other embodiments of the present disclosure, heat-rejecting media may include a heatpipe structure comprising a plurality of heatpipes, the plurality of heatpipes comprising a generally-cylindrical first pipe having a first cross-sectional area, a generally-cylindrical second pipe mechanically coupled to the first pipe having a second cross-sectional area less than the first cross-sectional area, and a generally-cylindrical third pipe mechanically coupled to the second pipe having a third cross-sectional area less than the second cross-sectional area, such that the second pipe is coupled between the first pipe and the third pipe and the first pipe, second pipe, and third pipe form a closed plenum, and a finstack structure comprising a plurality of fins mechanically and thermally coupled to the third pipe.

In accordance with these and other embodiments of the present disclosure, a method for fabricating a heatpipe structure may include coupling a generally-cylindrical first pipe having a first cross-sectional area to a generally-cylindrical second pipe, the second pipe having a second cross-sectional area less than the first cross-sectional area, coupling a generally-cylindrical third pipe to the second pipe, the third pipe having a third cross-sectional area less than the second cross-sectional area, the coupling such that the second pipe is coupled between the first pipe and the third pipe and the first pipe, second pipe, and third pipe form a closed plenum, and mechanically and thermally coupling a finstack structure comprising a plurality of fins to the third pipe.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system, in accordance with embodiments of the present disclosure;

FIGS. 2A through 2C illustrate various views of a single-finstack configuration of heat-rejecting media, in accordance with embodiments of the present disclosure; and

FIGS. 3A and 3B illustrate various views of a dual-finstack configuration of heat-rejecting media, in accordance with embodiments of the present disclosure.

### DETAILED DESCRIPTION

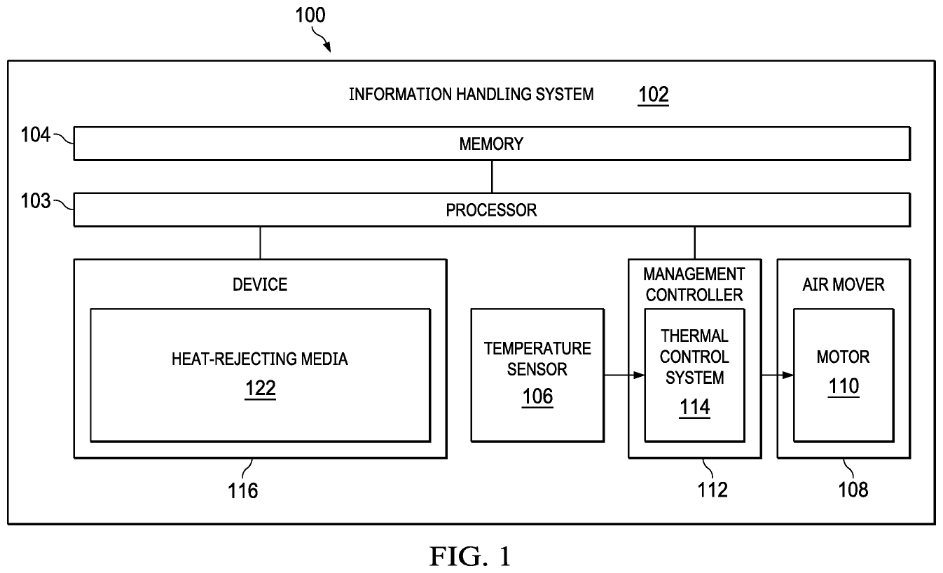

Preferred embodiments and their advantages are best understood by reference to FIGS. 1 through 3B, wherein like numbers are used to indicate like and corresponding parts.

For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a PDA, a consumer electronic device, a network storage device, or any other suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, buses, memories, I/O devices and/or interfaces, storage resources, network interfaces, motherboards, integrated circuit packages; electro-mechanical devices (e.g., air movers), displays, and power supplies.

FIG. 1 illustrates a block diagram of an example information handling system 102, in accordance with embodiments of the present disclosure. In some embodiments, information handling system 102 may comprise a server chassis configured to house a plurality of servers or “blades.” In other embodiments, information handling system 102 may comprise a personal computer (e.g., a desktop computer, laptop computer, mobile computer, and/or notebook computer). In yet other embodiments, information handling system 102 may comprise a storage enclosure configured to house a plurality of physical disk drives and/or other computer-readable media for storing data. As shown in FIG. 1, information handling system 102 may include a chassis 100 housing a processor 103, a memory 104, a temperature sensor 106, a air mover 108, a management controller 112, a device 116, and heat-rejecting media 122.

Processor 103 may comprise any system, device, or apparatus operable to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored in memory 104 and/or another component of information handling system 102.

Memory 104 may be communicatively coupled to processor 103 and may comprise any system, device, or apparatus operable to retain program instructions or data for a period of time. Memory 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off.

Air mover 108 may include any mechanical or electro-mechanical system, apparatus, or device operable to move air and/or other gases in order to cool information handling resources of information handling system 102. In some embodiments, air mover 108 may comprise a fan (e.g., a rotating arrangement of vanes or blades which act on the air). In other embodiments, air mover 108 may comprise a blower (e.g., a centrifugal fan that employs rotating impellers to accelerate air received at its intake and change the direction of the airflow). In these and other embodiments, rotating and other moving components of air mover 108 may be driven by a motor 110. The rotational speed of motor 110 may be controlled by an air mover control signal communicated from thermal control system 114 of management controller 112. In operation, air mover 108 may cool information handling resources of information handling system 102 by drawing cool air into an enclosure housing the information handling resources from outside the chassis, expelling warm air from inside the enclosure to the outside of such enclosure, and/or moving air across one or more heat sinks (not explicitly shown) internal to the enclosure to cool one or more information handling resources.

Management controller 112 may comprise any system, device, or apparatus configured to facilitate management and/or control of information handling system 102 and/or one or more of its component information handling resources. Management controller 112 may be configured to issue commands and/or other signals to manage and/or control information handling system 102 and/or its information handling resources. Management controller 112 may comprise a microprocessor, microcontroller, DSP, ASIC, field programmable gate array (“FPGA”), EEPROM, or any combination thereof. Management controller 112 also may be configured to provide out-of-band management facilities for management of information handling system 102. Such management may be made by management controller 112 even if information handling system 102 is powered off or powered to a standby state. In certain embodiments, management controller 112 may include or may be an integral part of a baseboard management controller (BMC), a remote access controller (e.g., a Dell Remote Access Controller or Integrated Dell Remote Access Controller), or an enclosure controller. In other embodiments, management controller 112 may include or may be an integral part of a chassis management controller (CMC).

As shown in FIG. 1, management controller 112 may include a thermal control system 114. Thermal control system 114 may include any system, device, or apparatus configured to receive one or more signals indicative of one or more temperatures within information handling system 102 (e.g., one or more signals from one or more temperature sensors 106), and based on such signals, calculate an air mover driving signal to maintain an appropriate level of cooling, increase cooling, or decrease cooling, as appropriate, and communicate such air mover driving signal to air mover 108. In these and other embodiments, thermal control system 114 may be configured to receive information from other information handling resources and calculate the air mover driving signal based on such received information in addition to temperature information. For example, as described in greater detail below, thermal control system 114 may receive configuration data from device 116 and/or other information handling resources of information handling system 102, which may include thermal requirements information of one or more information handling resources. In addition to temperature information collected from sensors within information handling system 102, thermal control system 114 may also calculate the air mover driving signal based on such information received from information handling resources.

Temperature sensor 106 may be any system, device, or apparatus (e.g., a thermometer, thermistor, etc.) configured to communicate a signal to management controller 112 or another controller indicative of a temperature within information handling system 102. In many embodiments, information handling system 102 may comprise a plurality of temperature sensors 106, wherein each temperature sensor 106 detects a temperature of a particular component and/or location within information handling system 102.

Device 116 may comprise any component information handling system of information handling system 102, including without limitation processors, buses, memories, I/O devices and/or interfaces, storage resources, network interfaces, motherboards, integrated circuit packages; electro-mechanical devices, displays, and power supplies.

As shown in FIG. 1, device 116 may have mechanically and thermally coupled thereto heat-rejecting media 122. Heat-rejecting media 122 may include any system, device, or apparatus configured to transfer heat from an information handling resource (e.g., device 116, as shown in FIG. 1), thus reducing a temperature of the information handling resource. For example, heat-rejecting media 122 may include a solid thermally coupled to the information handling resource (e.g., heatpipe, heat spreader, heatsink, finstack, etc.) such that heat generated by the information handling resource is transferred from the information handling resource into air surrounding the information handling resource. For example, in the embodiments represented by FIG. 1, heat-rejecting media 122 may be thermally coupled to device 116 and arranged such that heat generated by device 116 is transferred to air driven by air mover 108.

In addition to processor 103, memory 104, temperature sensor 106, air mover 108, management controller 112, device 116, and heat-rejecting media 122, information handling system 102 may include one or more other information handling resources. In addition, for the sake of clarity and exposition of the present disclosure, FIG. 1 depicts only one air mover 108 and one device 116. In embodiments of the present disclosure, information handling system 102 may include any number of air movers 108 and devices 116. However, in some embodiments, approaches similar or identical to those used to cool device 116 as described herein may be employed to provide cooling of processor 103, memory 104, management controller 112, and/or any other information handling resource of information handling system 102.

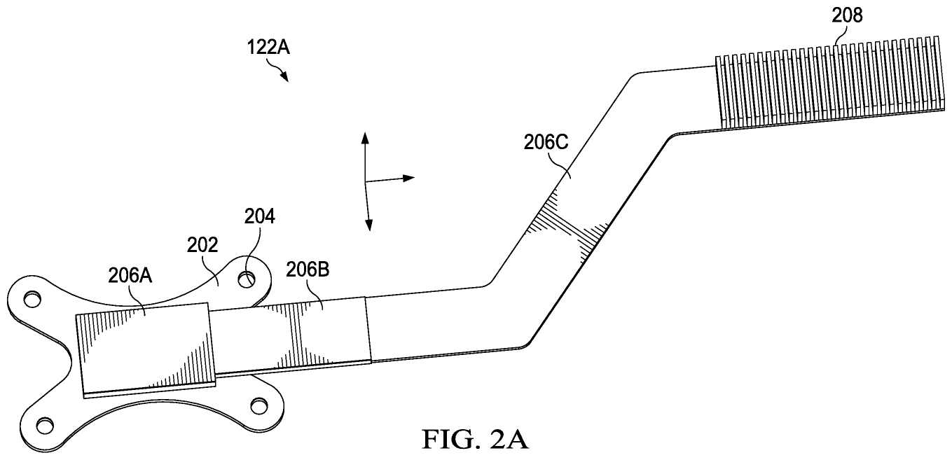

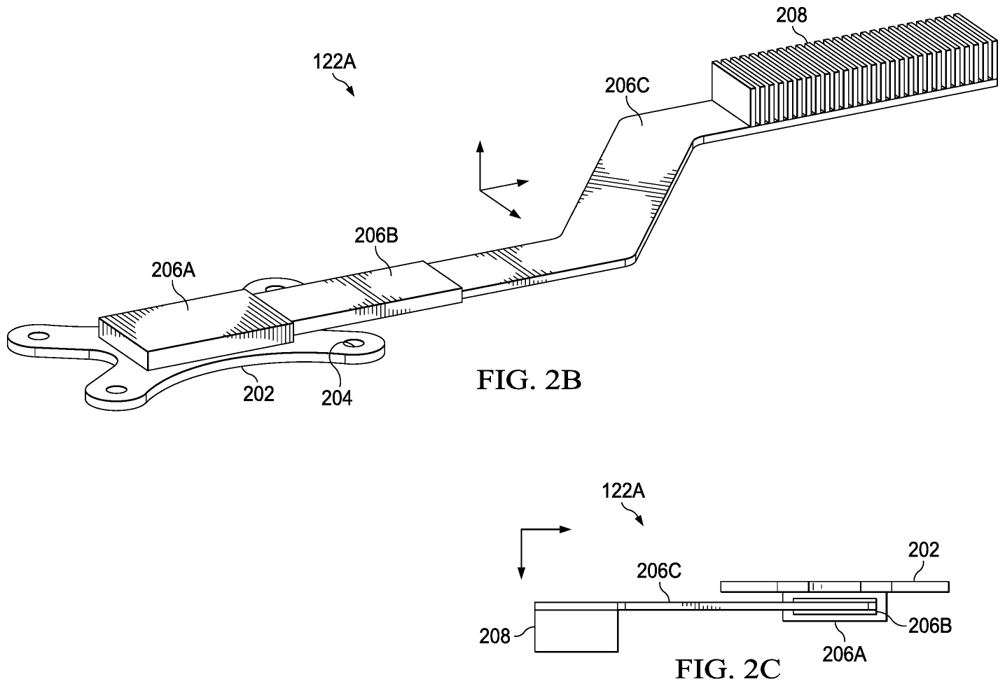

FIGS. 2A through 2C illustrate various views of a single-finstack configuration of heat-rejecting media 122A, in accordance with embodiments of the present disclosure. FIG. 2A depicts a top-down plan view of heat-rejecting media 122A, FIG. 2B depicts a isometric perspective view of hear-rejecting media 122A, and FIG. 2C depicts a side elevation view as seen looking from the right side of FIG. 2A. As shown in FIGS. 2A through 2C, heat-rejecting media 122A may include a baseplate 202, a tiered heatpipe structure 206 comprising pipes 206A, 206B, and 206C, and a finstack 208.

Baseplate 202 may comprise a substantially flat piece of thermally-conductive material (e.g., metal). As shown in FIGS. 2A through 2C, baseplate 202 may include a plurality of openings 204 for receiving mechanical fasteners (e.g., screws) that may impose a mechanical loading force upon baseplate 202 to contact baseplate 202 to device 116 on a surface of baseplate 202 opposite to that of pipe 206A, thus thermally coupling heat-rejecting media 122 to device 116.

Heatpipe structure 206 may comprise first pipe 206A, second pipe 206B, and third pipe 206C. Each of pipes 206A, 206B, and 206C may each comprise a generally cylindrical (e.g., circular cylinder or rectangular cylinder) piece of thermally-conductive material (e.g., metal) having a plenum at its interior for containing and conveying fluid (e.g., gas or liquid). First pipe 206A may be mechanically coupled (e.g., brazed, friction welded, soldered, or adhered via high-strength adhesive) to baseplate 202, thus thermally coupling first pipe 206A to baseplate 202, such that heat may be transferred from device 116 to first pipe 206A. First pipe 206A may have a first cross-sectional area perpendicular to a center axis of first pipe 206A. Second pipe 206B may have a second cross-sectional area perpendicular to a center axis of second pipe 206B, wherein the second cross-sectional area is smaller than that of the first cross-sectional area, and may be mechanically coupled (e.g., brazed, friction welded, soldered, or adhered via high-strength adhesive) to one first pipe 206A such that an opening of the plenum of second pipe 206B is in fluid communication with the plenum of first pipe 206A. Likewise, third pipe 206C may have a third cross-sectional area perpendicular to a center axis of third pipe 206C, wherein the third cross-sectional area is smaller than that of the second cross-sectional area, and may be mechanically coupled (e.g., brazed, friction welded, soldered, or adhered via high-strength adhesive) to second pipe 206B such that an opening of the plenum of second pipe 206B is in fluid communication with the plenum of third pipe 206C. In addition, each of pipe 206A and 206C may have a closed end, such that pipes 206A, 206B, and 206C form a heatpipe structure 206 that includes a closed plenum extending from the closed end of pipe 206A to the closed end of pipe 206C. Such closed plenum may function as a thermal evaporator.

Finstack 208 may comprise a plurality of generally-parallel fins of thermally-conductive material (e.g., metal), each fin mechanically coupled to pipe 206C, thus thermally coupling each such fin to pipe 206C.

Accordingly, in operation, heat generated by device 116 may be conveyed from device 116 through baseplate 202, through heatpipe structure 206, and to finstack 208, from which heat may be transferred to air.

Heat-rejecting media 122A is thus implemented using a plurality (e.g., three or more) of pipes 206A, 206B, and 206C of decreasing cross-sectional area to form a heatpipe structure 206 that allows for a larger area of contact between the heatpipe structure 206 as compared to traditional approaches, while reducing the width of the heatpipe structure 206 to finstack 208 as compared to traditional approaches. Once pipes 206A, 206B, and 206C have been integrated, a sintering process may be completed using a tiered mandrel to keep the sintered particle layer consistent and in contact through each transition of the heatpipe. Further thinning of pipe wall local flaring of the heatpipe structure 206 may be completed to ensure minimization of the wall thickness of heatpipe structure 206.

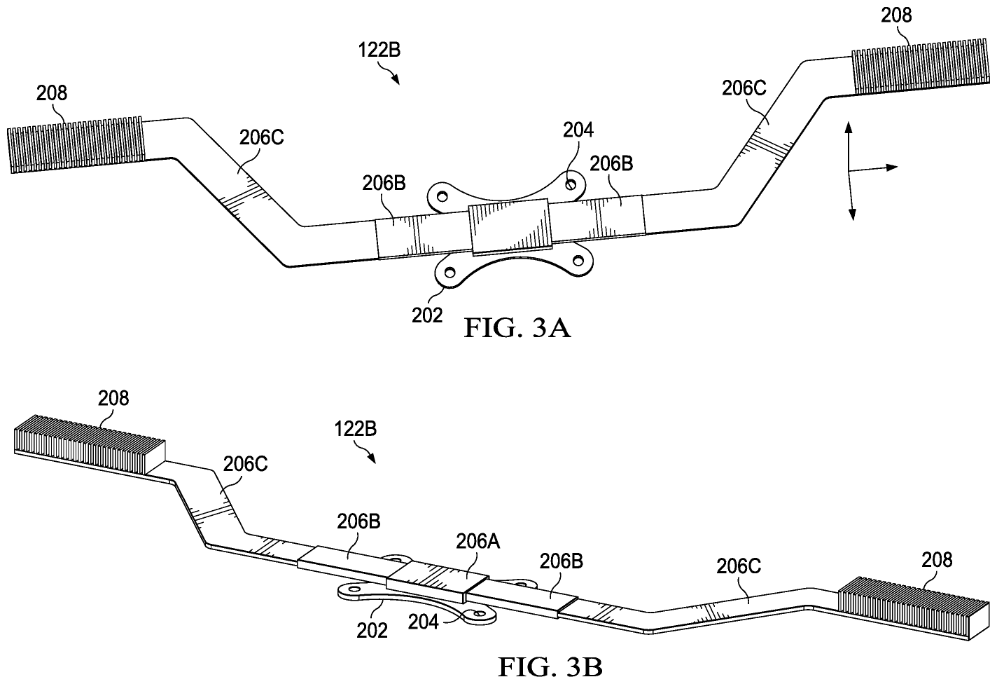

FIGS. 3A and 3B illustrate various isometric perspective views of a dual-finstack configuration of heat-rejecting media 122B, in accordance with embodiments of the present disclosure. In many respects, heat-rejecting media 122B is similar to heat-rejecting media 122A, and thus only the differences between heat-rejecting media 122B and heat-rejecting media 122A may be described below. The main difference between heat-rejecting media 122B and heat-rejecting media 122A is that pipe 206A of heat-rejecting media 122B may be open at both ends, such that individual second pipes 206B are mechanically coupled to each end of first pipe 206A (with each second pipe 206B having a smaller cross-sectional area than first pipe 206A), and a respective third pipe 206C is mechanically coupled to each second pipe 206B (with each respective third pipe 206C having a smaller cross-sectional area than its corresponding second pipe 206B), with a finstack 208 respectively mechanically and thermally coupled to each third pipe 206C, such that heat generated by device 116 is conveyed to both finstacks 208. In some embodiments, each second pipe 206B may be identical or similar in size and shape. In these and other embodiments, each third pipe 206C may be identical or similar in size and shape.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. An information handling system comprising:
an information handling resource;
heat-rejecting media thermally coupled to the information handling resource, the heat rejecting media comprising:
a heatpipe structure comprising a plurality of heatpipes, the plurality of heatpipes comprising:
a generally-cylindrical first pipe mechanically coupled at a location proximate the information handling resource and having a first cross-sectional area based on a first height and a first lateral width;
a generally-cylindrical second pipe mechanically coupled to the first pipe having a second cross-sectional area based on a second height and a second lateral width, wherein the second cross-sectional area is less than the first cross-sectional area and the second lateral width is less than the first lateral width; and
a generally-cylindrical third pipe mechanically coupled to the second pipe having a third cross-sectional area based on a third height and a third lateral width, wherein the third cross-sectional area is less than the second cross-sectional area and the third lateral width is less than the second lateral width, such that the second pipe is coupled between the first pipe and the third pipe, and the first pipe, second pipe, and third pipe form a closed plenum; and
a finstack structure comprising a plurality of fins mechanically and thermally coupled to the third pipe.

2. The information handling system of claim 1, wherein the heat-rejecting media further comprises a thermally-conductive baseplate mechanically coupled between the information handling resource and the first pipe.

3. The information handling system of claim 1, wherein at least one of the first pipe, second pipe, and third pipe is rectangular cylindrical in shape.

4. The information handling system of claim 1, wherein:
the plurality of heatpipes further comprise:
a generally-cylindrical fourth pipe mechanically coupled to the first pipe having a fourth cross-sectional area less than the first cross-sectional area; and
a generally-cylindrical fifth pipe mechanically coupled to the fourth pipe having a fifth cross-sectional area less than the fourth cross-sectional area, such that the fourth pipe is coupled between the first pipe and the fifth pipe and such that the first pipe, second pipe, third pipe, fourth pipe, and fifth pipe form a closed plenum; and
the heat-rejecting media further comprises a second finstack structure comprising a plurality of fins mechanically and thermally coupled to the fifth pipe.

5. The information handling system of claim 4, wherein the second cross-sectional area is equal to the fourth cross-sectional area.

6. The information handling system of claim 4, wherein the third cross-sectional area is equal to the fifth cross-sectional area.

7. Heat-rejecting media comprising:
a heatpipe structure comprising a plurality of heatpipes, the plurality of heatpipes comprising:
a generally-cylindrical first pipe having a first cross-sectional area based on a first height and a first lateral width;
a generally-cylindrical second pipe mechanically coupled to the first pipe having a second cross-sectional area based on a second height and a second lateral width, wherein the second cross-sectional area is less than the first cross-sectional area and the second lateral width is less than the first lateral width; and
a generally-cylindrical third pipe mechanically coupled to the second pipe having a third cross-sectional area based on a third height and a third lateral width, wherein the third cross-sectional area is less than the second cross-sectional area and the third lateral width is less than the second lateral width, such that the second pipe is coupled between the first pipe and the third pipe, and the first pipe, second pipe, and third pipe form a closed plenum; and
a finstack structure comprising a plurality of fins mechanically and thermally coupled to the third pipe.

8. The heat-rejecting media of claim 7, further comprising a thermally-conductive baseplate configured to be mechanically coupled between the information handling resource and the first pipe.

9. The heat-rejecting media of claim 7, wherein at least one of the first pipe, second pipe, and third pipe is rectangular cylindrical in shape.

10. The heat-rejecting media of claim 7, wherein:
the plurality of heatpipes further comprise:
a generally-cylindrical fourth pipe mechanically coupled to the first pipe having a fourth cross-sectional area less than the first cross-sectional area; and
a generally-cylindrical fifth pipe mechanically coupled to the fourth pipe having a fifth cross-sectional area less than the fourth cross-sectional area, such that the fourth pipe is coupled between the first pipe and the fifth pipe and such that the first pipe, second pipe, third pipe, fourth pipe, and fifth pipe form a closed plenum; and
the heat-rejecting media further comprises a second finstack structure comprising a plurality of fins mechanically and thermally coupled to the fifth pipe.

11. The heat-rejecting media of claim 10, wherein the second cross-sectional area is equal to the fourth cross-sectional area.

12. The heat-rejecting media of claim 10, wherein the third cross-sectional area is equal to the fifth cross-sectional area.

13. A method for fabricating a heatpipe structure comprising:
coupling a generally-cylindrical first pipe having a first cross-sectional area to a generally-cylindrical second pipe, the second pipe having a second cross-sectional area less than the first cross-sectional area;
coupling a generally-cylindrical third pipe to the second pipe, the third pipe having a third cross-sectional area less than the second cross-sectional area, the coupling such that the second pipe is coupled between the first pipe and the third pipe, and the first pipe, second pipe, and third pipe form a closed plenum; and
mechanically and thermally coupling a finstack structure comprising a plurality of fins to the third pipe.

14. The method of claim 13, further comprising mechanically coupling the first pipe to a thermally-conductive baseplate configured to be mechanically coupled between the information handling resource and the first pipe.

15. The method of claim 13, wherein at least one of the first pipe, second pipe, and third pipe is rectangular cylindrical in shape.

16. The method of claim 13, further comprising:
mechanically coupling a generally-cylindrical fourth pipe to the first pipe having a fourth cross-sectional area less than the first cross-sectional area;
mechanically coupling a generally-cylindrical fifth pipe to the fourth pipe having a fifth cross-sectional area less than the fourth cross-sectional area, such that the fourth pipe is coupled between the first pipe and the fifth pipe and such that the first pipe, second pipe, third pipe, fourth pipe, and fifth pipe form a closed plenum; and
mechanically and thermally coupling a second finstack structure comprising a plurality of fins to the fifth pipe.

17. The method of claim 16, wherein the second cross-sectional area is equal to the fourth cross-sectional area.

18. The method of claim 16, wherein the third cross-sectional area is equal to the fifth cross-sectional area.
